(19) United States
(12) Patent Application Publication
(10) Pub. No.: US 2023/0220553 A1
(43) Pub. Date: Jul. 13, 2023

(54) DEVICE AND METHOD FOR EVAPORATING AN ORGANIC POWDER

(71) Applicant: AIXTRON SE, Herzogenrath (DE)

(72) Inventors: Markus JAKOB, Monschau (DE); Andy EICHLER, Aachen (DE)

(21) Appl. No.: 18/009,675

(22) PCT Filed: Jun. 16, 2021
(86) PCT No.: PCT/EP2021/066210

§ 371 Date: Dec. 9, 2022

(30) Foreign Application Priority Data
Jun. 19, 2020 (DE) 10 2020 116 271.5

(51) Int. Cl. C23C 16/52; C23C 14/12; B01D 1/00; B01D 1/14; C23C 14/24; C23C 14/54; C23C 16/448; C23C 16/455; G01L 9/00; G05D 11/13

(52) U.S. Cl. CPC C23C 16/52; B01D 1/14; B01D 1/0082; C23C 14/12; C23C 14/246; C23C 14/543; C23C 16/4483; C23C 16/45561; G01L 9/0005; G05D 11/139

(57) ABSTRACT

In a method for evaporating a non-gaseous starting material, the starting material is introduced into an evaporation chamber; an evaporation element heats the starting material to create a vapor; a conveying gas flow transports the vapor through a conveying channel and past a sensor, which measures the concentration or partial pressure of the vapor in the gas flow flowing through the conveying channel; and the mass flow of the vapor through the conveying channel is controlled by varying the conveying gas flow with respect to a setpoint value. To keep the vapor flow largely constant over time, a compensating gas flow is fed into the conveying channel at a mixing point disposed between the evaporator and the sensor. A second mass flow controller controls the mass flow of the compensating gas flow such that, when the conveying gas flow varies, the gas flow flowing past the sensor remains constant.

### RELATED APPLICATIONS

This application is a National Stage under 35 USC 371 of and claims priority to International Application No. PCT/EP2021/066210, filed 16 Jun. 2021, which claims the priority benefit of DE Application No. 10 2020 116 271.5, filed 19 Jun. 2020.

### FIELD OF THE INVENTION

The invention relates to a method for vaporizing a non-gaseous starting material, in which a non-gaseous starting material is brought into a vaporization chamber of a vaporizer, a vaporization structure of the vaporizer supplies heat to the starting material so that it vaporizes to form a vapor, the vapor is transported by means of a conveying gas stream which is fed into the vaporization chamber through a gas supply line, the mass flow of which conveying gas stream being controlled by a first mass flow controller, through a conveying conduit past a sensor which measures the concentration or the partial pressure of the vapor in the gas stream flowing through the conveying conduit, and the mass flow of the vapor through the conveying conduit is controlled by variation of the conveying gas stream against a nominal value.

Furthermore, the invention relates to a device for vaporizing a non-gaseous starting material, with a vaporizer which has a vaporization chamber and a vaporization structure which can be heated, with which the starting material brought into the vaporization chamber is vaporized to form a vapor, with a gas supply line which discharges into the vaporization chamber and has a first mass flow controller for feeding a conveying gas stream into the vaporization chamber, with a conveying conduit emanating from the vaporization chamber in order to transport the vapor with the conveying gas stream to a sensor which is disposed in the conveying conduit and which measures the concentration or the partial pressure of the vapor in the gas stream flowing through the conveying conduit, and with a control device for controlling the mass flow of the vapor through the conveying conduit against a nominal value by variation of the conveying gas stream.

### BACKGROUND

A device for vaporizing an organic powder is described in DE 10 2020 103 822. A quantified quantity of powder is brought into an intermediate reservoir with a metering device, from which it is brought into a vaporization chamber of a vaporizer through an infeed opening. In the vaporization chamber are vaporization structures which have been heated to a high temperature and which provide the heat of vaporization to the particles to be vaporized. The vapor which is produced is conveyed with a conveying gas stream which has been fed into the vaporization chamber through a conveying conduit to a gas inlet means of a reactor, with which OLED layers are deposited. A sensor is present in the conveying conduit and has a deposition surface on which the vapor condenses due to a temperature difference at a rate which is a function of the concentration or the partial pressure. The concentration or the partial pressure of the vapor in the conveying gas stream can be determined with the aid of the rate. The conveying gas stream is controlled with the aid of a first mass flow controller. By varying the conveying gas stream, the conveying rate of the vapor through the conveying conduit can be controlled against a nominal value. This is accompanied by a variation in the flow rate of the medium flowing through the conveying conduit.

The rate of vaporization in the vaporizer is influenced on the one hand by the temperature of the vaporization structure and on the other hand by the mean grain size of the powder. Temporal variations in vaporization in the vaporizer are compensated for by varying the flow rate in the conveying conduit with the aim of ensuring as constant as possible a mass flow of the vapor to the reactor. This is carried out via a PID controller which acts on the first mass flow controller. It has been observed that the measurement characteristics of the sensor are influenced by the total flow or the flow rate of the gas through the conveying conduit. In order to calculate values for the concentration or the partial pressure of the vapor in the conveying gas stream from the rate of deposition of the vapor on the deposition surface of the sensor, a “tooling factor” is used, which is a function of the gas flow. When the gas flow varies, then distortions occur in the measured values.

The prior art also includes US 2017/362701 A1, KR 101179872 B1, US 9,302,291 B2, EP 1 167 569 A1 and WO 2017/027581 A1.

DE 10 2015 104 240 A1 describes a device in which a mass flow controller is used to provide a controlled mass flow of a carrier gas, for example nitrogen. The mass flow of the carrier gas is fed into a vaporizer in which a non-gaseous starting substance is vaporized by means of a vaporization structure. The non-gaseous starting substance is provided with the aid of a metering device. The metering device can temporally dispense a plurality of quantified quantities of the starting material one after the other. The discontinuous flow of the starting substance is conveyed in a carrier gas flow, in which an aerosol is formed. The aerosol is conveyed to the vaporization structure. Downstream of the vaporization structure is a QCM sensor, with which the partial pressure or the concentration of the vapor within the carrier gas flow can be determined. By using the value provided by the sensor, the concentration of the vapor in the carrier gas or the vapor transport rate can be varied by a control device by varying the carrier gas flow. Sensors of this type have also been described in DE 10 2017 106 967 A1 or DE 10 2017 106 968 A1. The disclosures of those publications are therefore incorporated in their entirety into the disclosure of the present application.

### SUMMARY OF THE INVENTION

The objective of the invention is to provide measures by means of which, in a device of the relevant type or in a method of the relevant type, the conveying rate of the vapor can be kept constant to a greater extent, in particular in order to deposit layers in an OLED reactor with a slow to medium growth rate with a reproducible layer thickness.

The objective is achieved by means of the invention as defined in the claims. The dependent claims not only define advantageous further embodiments of the technical disclosure defined in the subordinate claims, but also independent inventive solutions.

Firstly and essentially, the objective is achieved by feeding a compensating gas stream into the conveying conduit at a mixing point in the conveying conduit which lies between the vaporizer and the sensor. The compensating gas stream is provided from a compensating gas supply line in which a second mass flow controller is located. The second mass flow controller is controlled in a manner such that the total gas flow of the medium which flows past the sensor is kept constant even in the case of a variation in the conveying gas stream. In particular, the compensating gas stream is controlled in a manner such that at the sensor, a gas stream conveying the vapor flows past at a constant flow rate. To this end, in particular, the gas stream flowing through the compensating gas supply line is reduced by the mass flow by which the mass flow which flows through the conveying gas supply line is increased, and vice versa. Thus, in accordance with the invention, the mass flow controllers are operated in a push-pull manner. The sum of the mass flows remains constant, within a tolerance of the mass flow controller of ± 2 percent, for example, during the entire deposition process. In this manner, the flow rate stability of the vapor fed to the gas inlet means of the OLED reactor is higher compared with the prior art. The inventive improvement in the stability of the rate of the vaporization source arises for low vaporization rates in particular. The proven prior art technology for vaporizing the solid or liquid starting substance at a fixed vaporization temperature and stabilizing the flow rate by means of an adjustable carrier gas flow can be retained. The conveying gas stream which varies because of its mass flow of the carrier gas is diluted by means of a compensating gas stream in a manner such that the total mass flow of the carrier gas which flows past the sensor is kept constant. The conveying gas flow and the compensating gas flow may be provided from the same gas source, for example a nitrogen source. This has the advantage that the sensor, which is preferably a Quartz Crystal Monitor (QCM), can be operated with one tooling factor which is determined for only one flow rate. With a PID control device, with the aid of the measured values provided by the sensor, two mass flows which are fed into the conveying conduit can be controlled in a manner such that a vapor transport rate can be kept constant with time. The vapor produced is transported through a heated transport line to an OLED reactor in which a substrate, for example a glass substrate, may be located which is coated with one or more organic layers. To this end, the vapor conveyed through the conveying conduit is fed into a gas inlet means which has a plurality of gas outlet openings directed into a process chamber through which the vapor transported by the carrier gas is introduced into the process chamber of the reactor, so that the vapor can condense on a substrate lying on a cooled substrate holder. Reference to the descriptions provided in DE 10 2020 103 822 should be made for the configuration of the vaporizer. A reactor arrangement with vaporization source is shown, by way of example, in the FIGURE of DE 10 2019 128 515 or DE 10 2017 106 431 A1. The contents of the applications are hereby incorporated into the disclosure of this application.

### BRIEF DESCRIPTION OF THE DRAWINGS

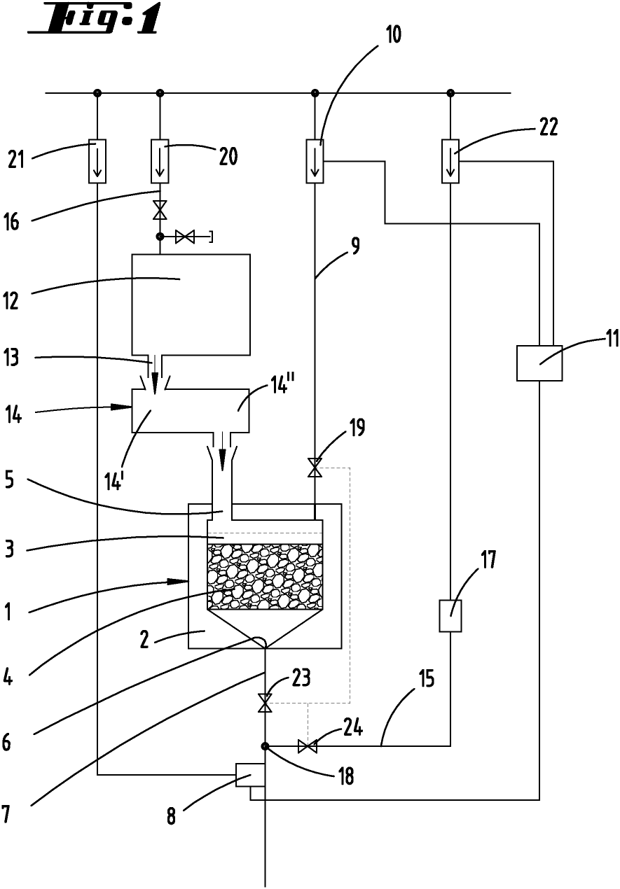

An exemplary embodiment of the invention will now be described with the aid of FIG. 1, which illustrates a device for evaporating a non-gaseous starting material in accordance with an embodiment of the present invention.

### DETAILED DESCRIPTION

FIG. 1 diagrammatically shows a source of vapor which has a metering device 12 for the preparation of a solid or liquid starting substance which is fed via an intermediate reservoir 14 into a vaporization chamber 3 of a vaporizer, in which the starting substance vaporizes in order to be transported through a conveying conduit 7 by means of a conveying gas stream to an OLED reactor, not shown.

The system depicted in FIG. 1 shows a metering device 12, which may have a storage container in which a powder of an organic material is stored. The powder may, for example, be transported to a dispensing point via a metering wheel with a plurality of metering chambers. The metering chambers may be formed by circular holes disposed on a flat disk about an axis of rotation. During the rotation of the flat disk, the holes, which are open towards the two broad sides of the disk, fill with the powder. At the dispensing point, a stream of carrier gas blows through one of these holes and transports the quantified quantity of the powder contained therein into a discharge line to which a conveying section is connected, by means of which a plurality of quantities of powder brought into the carrier gas stream are transported one after the other to an intermediate reservoir 14.

The rate of the transported powder is specified by the rotational speed of the metering wheel. The quantity of powder supplied to the intermediate reservoir over the period within which the powder is supplied to the intermediate reservoir 14 at the constant rotational speed of the metering wheel can be determined. However, it is also possible to use other metering devices which convey the metered powder, either as an aerosol or not as an aerosol, in the direction of a vaporization chamber 3 of a vaporizer 1. In order to convey the aerosol, a carrier gas can be fed through a gas supply line 16 into the metering device 12, the mass flow of which can be controlled by means of a mass flow controller 20.

The optional intermediate reservoir 14 may have a collecting container in a cold region 14′ of the intermediate reservoir 14 which is filled continuously. The collecting container may be brought at regular or irregular intervals to a hot region 14″ of the intermediate reservoir 14 in order to be emptied from there. In this regard, the contents of the collecting container are conveyed through an infeed opening 5 into the vaporizer 1 by means of a gas stream. The temperature in the hot region 14″ of the intermediate reservoir 14 may be above the vaporization temperature of the starting substance. However, it is also possible to feed the starting substance into the vaporizer 1 directly from the metering device 12.

The vaporizer 1 has a first infeed opening 5 through which the starting substance is conveyed into the vaporization chamber 3 of the vaporizer 1 with or without carrier gas. The vaporizer 1 has a second infeed opening. A conveying gas stream flowing through a gas supply line 9 can be fed into the vaporizer 1 through the second infeed opening. A mass flow controller 10 controls the conveying gas stream. Furthermore, a valve 19 is located in the gas supply line 9.

The starting substance is fed into the vaporization chamber 3 in the form of solid or liquid particles which form part of an aerosol. The particles distribute themselves inside the vaporization structure 4 in an irregular manner and can be deposited on the surfaces of the vaporization structure 4 with an irregular thickness of material.

The vaporizer 1 has a heating device 2 with which a vaporization structure 4 disposed in the vaporization chamber 3 can be brought to a temperature at which the starting substance fed into the vaporization structure 4 can vaporize. The vaporization structure 4 may be a solid foam consisting of an electrically conductive material. By passing an electric current through the vaporization structure 4, energy with which the vaporization of the starting substance is carried out can be supplied to it. The vapor which is formed thereby is transported with the conveying gas stream to an outlet opening 6 of the vaporizer 1 from which a conveying conduit 7 issues, through which the vapor is transported to the OLED reactor (not shown).

The vaporization rate at which the starting substance is vaporized is a function on the one hand of the distribution of the particles on the surfaces of the vaporization structure 4, and on the other hand on the respective thickness of the material of a layer of particles to be vaporized on the surfaces, and furthermore on the particle size of the starting substance. Because the constant vaporization continuously varies the distribution of the particles and the thickness of the layers of particles deposited on the surfaces, variations occur in the vaporization rate.

The reference numeral 8 indicates a QCM sensor by which the flow of gas containing the vapor and the carrier gas of the conveying gas stream flows. The concentration or the partial pressure of the vapor inside the flow of gas can be determined with the sensor 8. To this end, the sensor 8 has a deposition surface which is maintained at a temperature which is below the condensation temperature of the vapor, so that condensate is deposited on the deposition surface. The rate of deposition is influenced by the concentration or the partial pressure of the vapor inside the conveying conduit 7. The concentration or the partial pressure of the vapor can be determined directly from the deposition rate by means of a tooling factor or a calibration function. A gas stream which is controlled with the mass flow controller 21 may, for example, be fed into the QCM sensor 8 for the purposes of maintenance or cleaning.

Because of the fluctuating vaporization rate, for a conveying gas stream which is kept constant, the QCM sensor 8 would measure a partial pressure of the vapor in the gas stream which varied substantially with time.

A control device 11 is provided, by means of which the mass flow of the vapor inside the conveying conduit 7 can be varied in order, in this manner, to regulate the mass flow of the vapor inside the conveying conduit 7 against a nominal value. To this end, the mass flow controller 10 inside the gas supply line 9 is controlled in order to vary the conveying gas stream. Using these measures, the substantial variation of the partial pressure of the vapor can be reduced. Furthermore, this measure alone can also vary the total flow of the gas flowing past the sensor 8, which could be seen to be a disadvantage because the sensor is calibrated to only one flow rate.

With a mass flow controller 22, which is preferably fed from the same gas source from which the mass flow controllers 21, 22 and 10 are also fed a compensating gas is provided which is fed into the conveying conduit 7 through a compensating gas supply line 15. A heating device 17, to heat the compensating gas to the same temperature to which the conveying conduit 7 is heated with a heating device, not shown, is located in the compensating gas supply line 15. The reference numerals 23 and 24 indicate valves which are located in the conveying conduit 7 or in the compensating gas supply line 15.

The mixing point 18 at which the compensating gas supply line 15 discharges into the conveying conduit 7 is located between the outlet opening 6 and the sensor 8. It is upstream of the sensor 8.

The mass flow controller 22 is controlled with the control device 11 in a manner such that the sum of the mass flows which flow through the mass flow controllers 10 and 22 remains constant. This has the desired consequence that the flow rate of the gas stream flowing by the sensor 8 remains constant. A variation of the conveying gas stream in one direction, i.e., an increase, for example, in order to regulate the mass flow of the vapor through the conveying conduit 7 against a nominal value has the same but opposite variation in the compensating gas stream, for example a reduction, as a consequence.

By means of the control device 11 and the mass flow controllers 22, 10 controlled by it, the vapor conveyed through the conveying conduit 7 can have a constant vapor rate, vapor concentration or the like, whereupon the mass flow of the carrier gas also remains constant within the tolerances. With the measures of the invention, the sensor 8 works with a greater accuracy of measurement because the concentrations or the partial pressure of the vapor is determined by the flow rate at which the sensor has been calibrated.

The description above serves to clarify the inventions encompassed by the application, which advance the prior art in at least the following combinations of features or even by themselves, wherein two, more or all of these combinations of features may also be combined, namely:

A method which is characterized in that a compensating gas stream is fed into the conveying conduit 7 at a mixing point 18 disposed between the vaporizer 1 and sensor 8, the mass flow of which compensating gas stream being controlled by a second mass flow controller 22 in a manner such that when the conveying gas stream varies, the gas stream flowing past the sensor 8 remains constant.

A device which is characterized in that a compensating gas supply line 15 having a second mass flow controller 22 discharges at a mixing point 18 disposed between the vaporizer 1 and sensor 8 and the control device 11 is configured to control the second mass flow controller 22 in a manner such that when the conveying gas stream varies, the gas stream flowing past the sensor 8 remains constant.

A method or a device which are characterized in that the sensor 8 past which the gas stream flows at a constant flow rate has a deposition surface on which the vapor condenses at a rate which is a function of the partial pressure or the concentration.

A method or a device which is characterized in that the sum of the mass flow controlled with the first mass flow controller 10 and with the second mass flow controller 22 is kept constant within a tolerance of the control accuracy of the mass flow controllers.

A method or a device which is characterized by a metering device 12 with which a measured quantity from a store of the starting material can be dispensed to the vaporizer 1.

A method or a device which is characterized in that the starting material is an organic powder and/or in that the sensor is a QCM sensor and/or in that the vaporization structure 4 is an open-pored solid foam and/or in that the conveying gas stream and the compensating gas stream are provided from one source of inert gas.

A method which is characterized in that organic layers or OLED layers are deposited onto a substrate with the vapor which is produced.

A device which is characterized in that the conveying conduit 7 discharges into a gas inlet means of a reactor which has a process chamber in which organic layers or OLED layers can be deposited on a substrate.

A method or a device which is characterized in that an intermediate reservoir 14 for the intermediate storage of the measured quantity of powder is provided between the metering device 12 and the vaporizer 1.

A method or a device which is characterized in that the intermediate reservoir 14 has a cold region 14′ in which the quantity of the starting substance measured with the metering device 12 is temporarily stored, and a hot region 14″ into which the measured quantity of the powder is brought in order to be supplied to the vaporizer 1 through an infeed opening 5 and/or in that a device for providing a quantified quantity of the starting material is disposed in the metering device 12, wherein a plurality of quantified quantities are brought temporally one after the other into a carrier gas flow provided from a gas supply line 16, with which the quantified quantities are transported to the intermediate reservoir 14 as an aerosol flow.

All of the disclosed features (independently but also in combination with each other) are essential to the invention. In the disclosure of the application, the disclosure of the associated/accompanying priority documents (copy of earlier application) are also incorporated therein in their entirety, with the intention that features of these documents may be taken up in the claims of the present invention. The features of the dependent claims, even without the features of a claim which is referred to are independent inventive embodiments of the prior art, in particular in order to make divisional applications on the basis of these claims. The invention defined in each claim may additionally have one or more of the features defined in the present description, in particular provided with reference numerals and/or appearing in the list of reference numerals. The invention also concerns embodiments in which individual features of the features cited in the present description are not implemented, in particular if they are manifestly dispensable as regards the respective purpose or can be replaced by other means with an identical technical effect.

List of Reference Numerals

| | |
|---|---|
| 1 | vaporizer |
| 2 | heating device |
| 3 | vaporization chamber |
| 4 | vaporization structure |
| 5 | infeed opening |
| 6 | outlet opening |
| 7 | conveying conduit |
| 8 | sensor |
| 9 | gas supply line |
| 10 | mass flow controller |
| 11 | control device |
| 12 | metering device |
| 13 | conveying section |
| 14 | intermediate reservoir |
| 14′ | cold region |
| 14″ | hot region |
| 15 | compensating gas supply line |
| 16 | gas supply line |
| 17 | heating device |
| 18 | mixing point |
| 19 | valve |
| 20 | mass flow controller |
| 21 | mass flow controller |
| 22 | mass flow controller |
| 23 | valve |
| 24 | valve |

1. A method for vaporizing a non-gaseous starting material, comprising:
transporting the starting material into a vaporization chamber (3) of a vaporizer (1);
supplying by a vaporization structure (4) of the vaporizer (1) heat to the starting material so as to vaporize the starting material into a vapor;
transporting the vapor through a conveying conduit (7) and past a deposition surface of a quartz crystal microbalance (OCM) sensor (8);
feeding a conveying gas stream into the vaporization chamber (3) through a first gas supply line (9);
controlling by a first mass flow controller (10) a mass flow of the conveying gas stream through the first gas supply line (9);
flowing a gas stream with the vapor through the conveying conduit (7) in a manner such that the vapor condenses on the deposition surface of the QCM sensor (8) at a rate which is a function of a concentration or a partial pressure of the vapor:
measuring by the OCM sensor (8) the concentration or the partial pressure of the vapor in the gas stream flowing through the conveying conduit (7);
controlling a mass flow of the vapor through the conveying conduit (7) by varying the mass flow of the conveying gas stream against a nominal value;
feeding a compensating gas stream into the conveying conduit (7) at a mixing point (18) disposed between the vaporizer (1) and the QCMsensor (8); and
controlling by a second mass flow controller (22) a mass flow of the compensating gas stream through a compensating gas supply line (15) such that when the conveying gas stream varies, a flow rate of a gas stream flowing past the deposition surface of the QCM sensor (8) remains constant.

2. A device for vaporizing a non-gaseous starting material, comprising:
a vaporizer (1) which has a vaporization chamber (3) and a vaporization structure (4) for heating the starting material transported into the vaporization chamber (3) so as to transform the starting material into is a vapor;
a gas supply line (9) which discharges into the vaporization chamber (3) and has a first mass flow controller (10) for feeding a conveying gas stream into the vaporization chamber (3);
a quartz crystal microbalance (OCM) sensor (8) with a deposition surface:
a conveying conduit (7) emanating from the vaporization chamber (3) for flowing a gas stream with the vapor from the vaporizer (1) to the QCM sensor (8) in a manner such that the vapor condenses on the deposition surface of the QCM sensor (8) at a rate which is a function of a concentration or a partial pressure of the vapor, wherein the OCM sensor (8) is disposed in the conveying conduit (7) and measures the concentration or the partial pressure of the vapor in the gas stream flowing through the conveying conduit (7);
a control device (11) for controlling a mass flow of the vapor through the conveying conduit (7) against a nominal value by varying a flow rate of the conveying gas stream; and
a compensating gas supply line (15) having a second mass flow controller (22) and fluidly coupled to a mixing point (18) disposed between the vaporizer (1) and the QCM sensor (8), wherein the control device (11) is further configured to control the second mass flow controller (22) in a manner such that when the conveying gas stream varies, a flow rate of a gas stream flowing past the deposition surface of the QCM sensor (8) remains constant.

3. (canceled)

4. The method of claim 1, wherein a sum of the mass flow of the conveying gas stream controlled with the first mass flow controller (10) and the mass flow of the compensating gas stream controlled with the second mass flow controller (22) is kept constant within a tolerance of a control accuracy of the first and second mass flow controllers (10, 22).

5. The device of claim 2, further comprising a metering device (12) for dispensing a measured quantity of the starting material from a store of the starting material.

6. The method of claim 1, wherein the starting material comprises an organic powder.

7. (canceled)

8. The device of claim 2, wherein the vaporization structure (4) comprises an open-pored solid foam.

9. The method of claim 1, further comprising depositing organic layers onto a substrate with the vapor which is produced by the vaporizer (1).

10. The device of claim 2, further comprising a reactor with gas inlet means and a process chamber , wherein the conveying conduit (7) is fluidly coupled to the gas inlet means.

11. The device of claim 5, further comprising an intermediate reservoir (14) disposed between the metering device (12) and the vaporizer (1), wherein the intermediate reservoir (14) is configured to temporarily store the measured quantity of starting material dispensed from the metering device (12).

12. The device of claim 11, wherein the intermediate reservoir (14) comprises a cold region (14′) in which the measured quantity of the starting material is temporarily stored, and a hot region (14″) into which the measured quantity of the starting material is transported from the cold region (14′) in order to be supplied to the vaporizer (1) through an infeed opening (5) of the vaporizer (1).

13. The method of claim 1, further comprising:
flowing a carrier gas flow through a second gas supply line (16);
transporting measured quantities of the starting material one after another into the carrier gas flow; and
transporting as an aerosol flow the measured quantities into an intermediate reservoir (14) comprising a cold region (14′) and a hot region (14″).

14. (canceled)

15. The method of claim 1, wherein the conveying gas stream and the compensating gas stream are supplied from a common source of inert gas.
